(19) United States
(12) Patent Application Publication
(10) Pub. No.: US 2011/0156157 A1
(43) Pub. Date: Jun. 30, 2011

(54) ONE-TIME PROGRAMMABLE CHARGE-TRAPPING NON-VOLATILE MEMORY DEVICE

(75) Inventors: Luca Milani, Brescia (IT); Rainer Herberholz, Cambridge (GB); David Vigar, Cambridge (GB)

(73) Assignee: CAMBRIDGE SILICON RADIO LTD., Cambridge (GB)

(21) Appl. No.: 13/045,754

(22) Filed: Mar. 11, 2011

Related U.S. Application Data
(63) Continuation-in-part of application No. 12/783,215, filed on May 19, 2010.

(30) Foreign Application Priority Data
Jun. 5, 2009 (GB) 0909686.8
Jun. 24, 2009 (TW) 98121178

(51) Int. Cl. H01L 27/092; H01L 21/8238; B05C 11/00

(52) U.S. Cl. 257/369; 438/200; 118/504; 257/E27.062; 257/E21.632

(57) ABSTRACT

A one-time programmable (OTP) charge-trapping non-volatile memory (NVM) device is described. In an embodiment, an OTP transistor is formed using a thick gate oxide typically used in producing an I/O MOS transistor and source/drain extensions which are highly doped, shallow and include pocket implants and which are typically used in producing a CORE thin-oxide MOS transistor. In an optimization, the OTP transistor may be formed with two narrow active areas instead of one wider active area. This provides increased performance compared to a device with a wider active area and reduced variability compared to a device with one narrow active area. In another embodiment, a dual gate oxide CMOS technology provides three types of transistor; a thin oxide device, a thick oxide device, and a thick oxide device using the implant type of the thin oxide device for providing an OTP charge-trapping NVM device.

### RELATED APPLICATIONS

This application is a continuation in part of U.S. application Ser. No. 12/783,215, filed on May 19, 2010. That application claimed the benefit of GB Application No. 0909686.8, filed on Jun. 5, 2009, and TW Application No. 98121178, filed on Jun. 24, 2009. The disclosures of all these related applications are incorporated herein by reference in their entirety.

### BACKGROUND

The scaling of CMOS technology leads to a greater difficulty in the integration of both floating gate memory and logic together for high performance and low power system-on-chip (SoC). The floating gate memory provides multi-time programmable memory (MTP) and embedded Flash memory. Embedded Flash memory is typically 2 or 3 nodes behind leading edge CMOS technology, because of the complexity of integrating additional processing (which also increases the costs). As a result, one-time programmable (OTP) memory is being used increasingly for embedded non-volatile memory (NVM) applications.

Two types of OTP memory are available on CMOS technology at or below 65 nm: electrical fuse (eFuse) and anti-fuse. An eFuse memory element is programmed by forcing a high current density through a conductive link in order to completely rupture it or make its resistance significantly higher such that the link is no longer conductive (the link is high resistance or open circuit). Anti-fuse is the opposite of an eFuse. The circuit is originally open (high resistance) and is programmed by applying electrical stress that creates a low resistance conductive path.

Neither eFuse or anti-fuse memory require additional process steps in a standard CMOS process; however as eFuse requires high current, it is programmed during production of the device and is not suited to programming during the operation of the chip on which it resides. The memory footprint of eFuse memory is also large and does not scale well with technology. Anti-fuse memory is low power such that a memory cell can be programmed at any stage and the memory footprint is smaller and scales with technology.

The use of charge trapping in MOS transistors, and in particular using hot carrier injection for programming, has been developed. However, programming typically requires high power and has low programming efficiency.

The embodiments described below are not limited to implementations which solve any or all of the disadvantages of known non-volatile memory.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

A one-time programmable (OTP) charge-trapping non-volatile memory (NVM) device is described. In an embodiment, an OTP transistor is formed using a thick gate oxide typically used in producing an I/O MOS transistor and source/drain extensions which are highly doped, shallow and include pocket implants and which are typically used in producing a CORE thin-oxide MOS transistor. In an optimization, the OTP transistor may be formed with two narrow active areas instead of one wider active area. This provides increased performance compared to a device with a wider active area and reduced variability compared to a device with one narrow active area. In another embodiment, a dual gate oxide CMOS technology provides three types of transistor; a thin oxide device, a thick oxide device, and a thick oxide device using the implant type of the thin oxide device for providing an OTP charge-trapping NVM device.

Many of the attendant features will be more readily appreciated as the same becomes better understood by reference to the following detailed description considered in connection with the accompanying drawings. The preferred features may be combined as appropriate, as would be apparent to a skilled person, and may be combined with any of the aspects of the invention.

### BRIEF DESCRIPTION OF THE DRAWINGS

Embodiments of the invention will be described, by way of example, with reference to the following drawings, in which:

FIG. 1 shows a schematic diagram of three types of transistor provided by CMOS technology using a new combination of doping schemes and gate-oxides;

FIG. 2 shows a schematic diagram of a mask set;

FIG. 3 shows a graph of threshold voltage against channel length;

FIG. 4 shows IDsat and IDlin graphs for varying threshold voltages;

FIG. 5 shows gds graphs for varying channel lengths;

FIG. 6 shows gds graphs for varying drain voltages;

FIG. 7 shows a graph of intrinsic gain against overdrive voltage;

FIG. 8 shows a graph exhibiting the matching of devices;

FIG. 9 shows another schematic diagram of three types of transistor provided by CMOS technology using another combination of doping schemes and gate-oxides;

FIG. 10 shows a schematic diagram of an OTP transistor in more detail;

FIG. 11 is an example graph which shows the effect of using different strength implants on threshold voltage;

FIG. 12 is a graph showing experimental results of the distribution of linear threshold voltages prior to programming for an example OTP transistor;

FIG. 13 shows a schematic diagram of another example mask set;

FIGS. 14 and 15 show designs of variants of an OTP array and OTP unit cell; and

FIG. 16 shows a data retention graph for different types of implant.

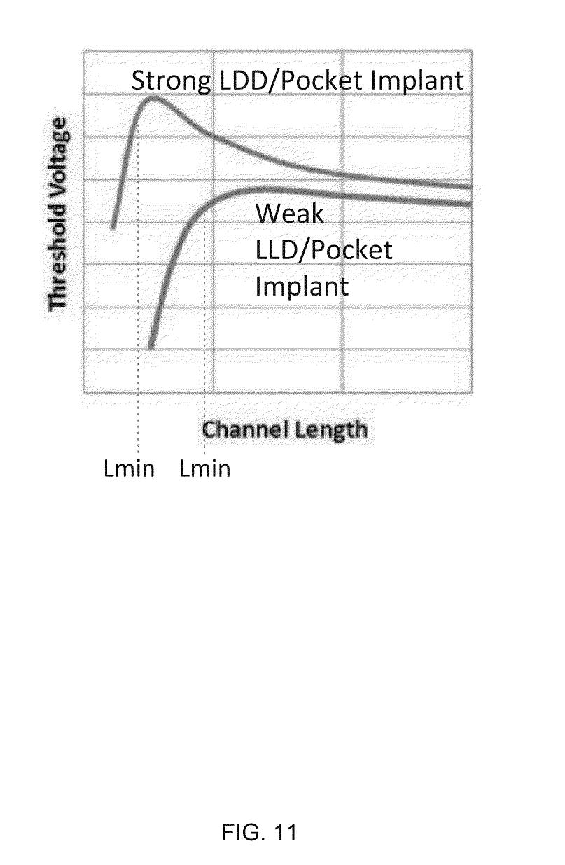

Like reference numerals are used to designate like parts in the accompanying drawings. It will be appreciated that the schematic diagrams showing cross-sections (e.g. FIG. 11) are not to scale.

### DETAILED DESCRIPTION

Embodiments of the present invention are described below by way of example only. These examples represent the best ways of putting the invention into practice that are currently known to the Applicant although they are not the only ways in which this could be achieved. The description sets forth the functions of the example and the sequence of steps for constructing and operating the example. However, the same or equivalent functions and sequences may be accomplished by different examples.

It will be understood that the phrase ‘CMOS technology’ is used herein to refer to a defined set of processes and options for the design and manufacture of CMOS devices. The phrase is not intended to be restrictive and should be read to also include BiCMOS and other process variants to which the following disclosure also applies.

The use of the word implant or implant condition is used in this disclosure to refer to any method by which dopants are introduced into CMOS devices, for example, but not limited to, ion implantation. The methods and techniques described herein are independent of the methods used to introduce dopants.

Where references are made to mask properties, the term ‘open’ or ‘opening’ is used to indicate that during wafer processing, the mask causes the creation of a related feature (i.e. oxide or implant) at that location. This term is used for convenience and is not intended to indicate that the physical mask has an actual opening, but is rather indicative of the function of the area of the mask.

CMOS technologies generally provide two types of MOSFET, a thin-oxide (core) MOSFET and a thick-oxide (I/O) MOSFET. The core devices are optimized to provide high switching speed and high integration density, while the I/O devices are designed to provide a robust interface to external components at voltages higher than can be tolerated in the core devices.

Process options for multiple threshold voltages in core devices are generally provided, but each option requires additional masking steps to adjust the channel doping. Furthermore, beyond the 65 nm process node, pocket implants are generally used to define transistor type, rather than well and channel implants. Different device types therefore have very similar long-channel threshold voltages and so low-threshold short-channel devices are not useful to increase the available voltage headroom in long-channel devices for analogue circuits.

Additional types of transistor can be provided by the use of additional processing steps. However, such an approach is expensive and development often lags behind leading-edge CMOS technologies.

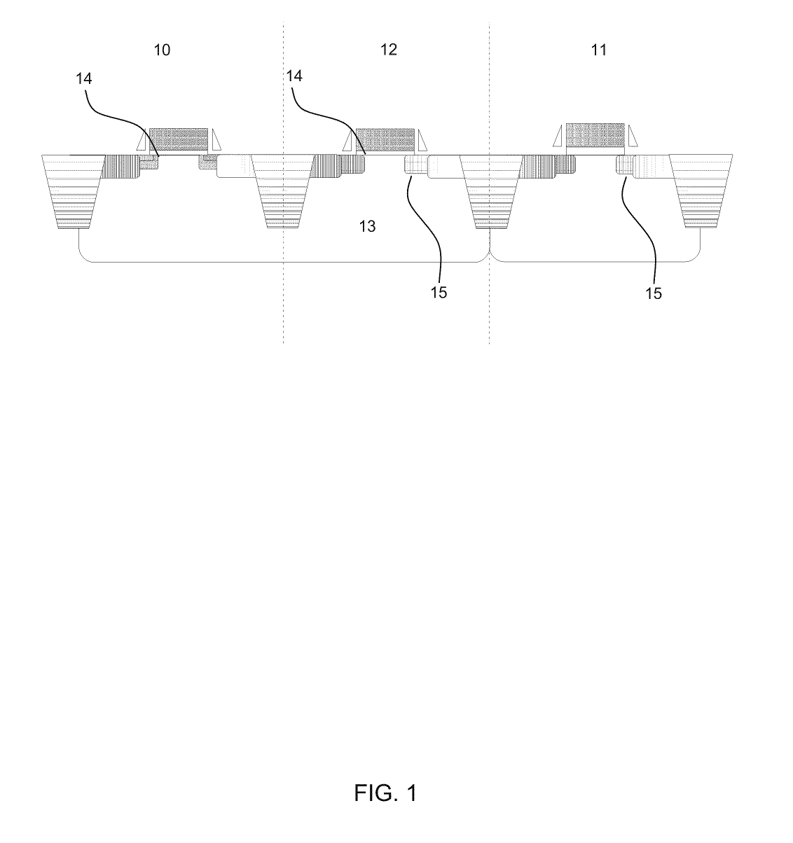

It has now been shown that a transistor having an improved performance can be fabricated by combining certain features from thin and thick oxide transistors in a dual oxide CMOS technology. FIG. 1 shows a cross section of conventional thin-oxide (core) 10 and thick-oxide (I/O) MOSFET devices 11, together with an analogue thin-oxide transistor (AVT) 12. The AVT is formed in the core p-well 13, and utilizes the thin gate-oxide 14 of the core devices, but uses the LDD implants 15 of the I/O device.

The conventional CMOS technology provides two types of transistor, however, by using different combinations of process steps (gate oxides and doping schemes) three or four types of transistor can be provided. Where the term conventional CMOS technology is used herein it is used to describe a technology providing base devices from which features may be combined according to the current disclosure. This description has been given in the context of a technology providing two transistor types for different supply voltages, but the conventional CMOS technology to which the methods described herein may be applied may provide more than two transistor types. Similarly, the methods described herein apply to all modifications and variants of the basic CMOS processes.

The provision of the AVT transistor 12 by the modified CMOS technology does not require any additional processing or development beyond the core 10 and I/O 11 devices provided by the conventional CMOS technology. The AVT transistor can therefore be provided without additional cost or manufacturing cycle time.

The AVT transistor may be provided by an extension of the Process Design Kit (PDK) in relation to the CMOS technology. The provision of new rules, design options and models allow the use of the new AVT transistor within designs using the modified CMOS technology. As explained previously, the provision of the new transistor type does not require additional processing steps and so the wafer manufacturing process remains conventional, although new mask layouts are created by the new rules which lead to the definition of new, previously unavailable, combinations of devices in the ICs formed according to the modified CMOS technology.

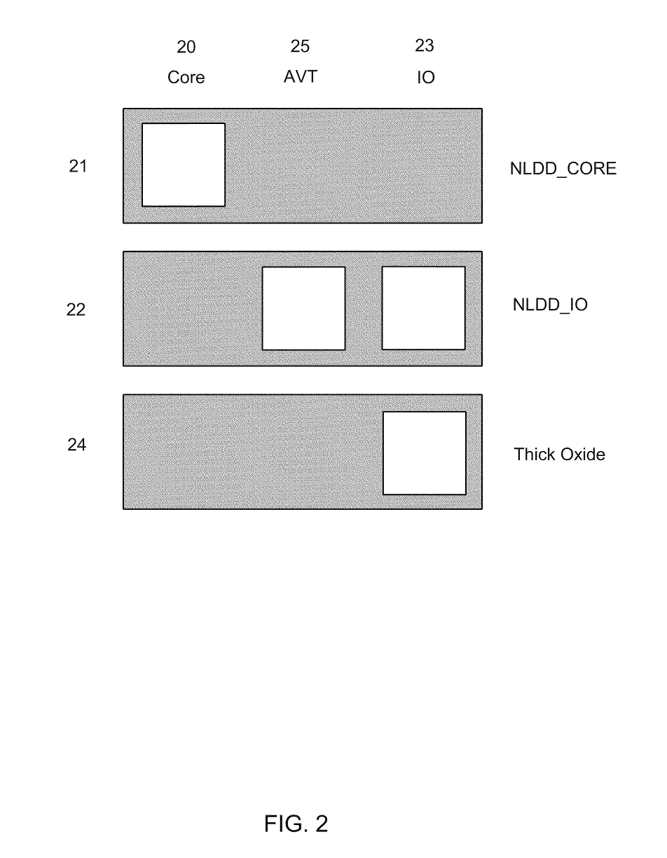

FIG. 2 shows a schematic diagram of a mask set for defining thin-oxide core, AVT and thick-oxide I/O transistors according to the modified CMOS technology. Openings in the mask show devices for which that process step is applied to for a particular device. As explained above, the word opening is not used to indicate a physical opening, but rather that that process step is applied to the indicated device. The active area, well & channel implants, gate-electrode and N⁺ or P+ masks are not shown as those steps are independent of the subject of this disclosure.

For the core device 20 the NLDD_CORE implant mask 21 (LDD/pocket for thin gate oxide devices) is open but the NLDD_IO implant mask 22 (LDD/pocket mask for thick gate oxide devices) is closed. In contrast the NLDD_IO implant mask 22 is open for the I/O device 23, but the NLDD implant mask 21 is closed. The thick oxide mask 24 is open only for the thick-oxide I/O device 23. For the avoidance of doubt, for devices where the thick oxide mask is closed, a thin oxide is assumed to be present.

For the conventional devices, the NLDD_CORE mask 21 can therefore be written logically as [N+ AND ACTIVE-AREA NOT THICK-OXIDE], and the NLDD_IO mask 22 can be written logically as [N+ AND ACTIVE-AREA AND THICK-OXIDE].

The AVT device 25 utilizes a new combination of features for the NLDD_IO mask 22, and introduces the combination [N+ AND ACTIVE-AREA AND AVT_LDD], where AVT_LDD is a marker layer marking AVT devices.

The AVT device of the current disclosure is thus obtained by new features of the PDK utilized in the design of integrated circuits and in the mask manufacture process. The modified CMOS technology provides new combinations of mask openings to provide the AVT device without adding process steps. An AVT device is thus characterized by utilizing a combination of features from the core and I/O devices provided by the conventional CMOS technology.

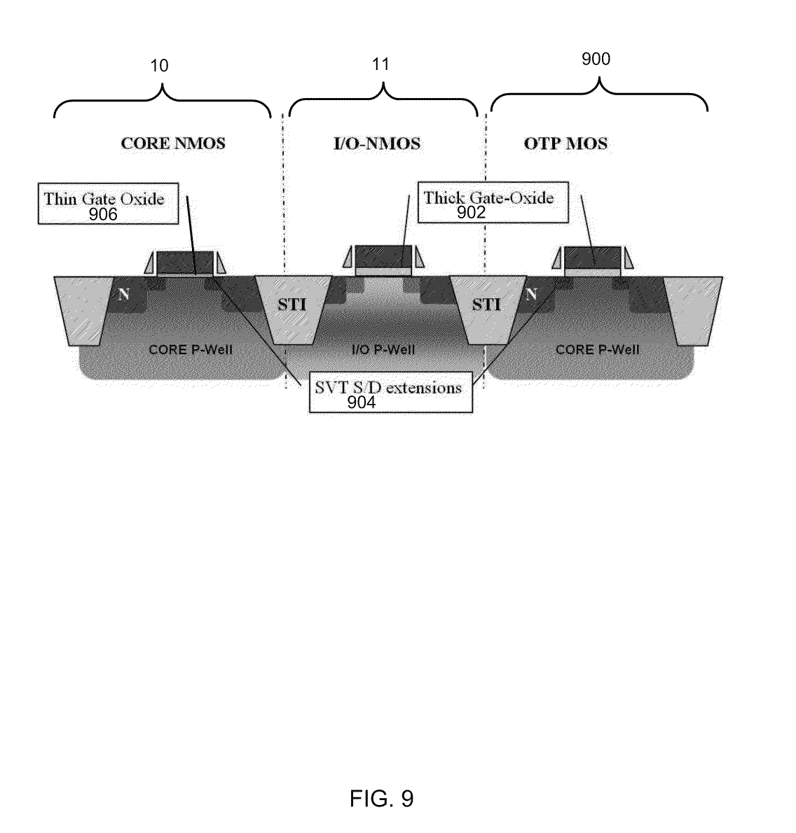

ICs utilizing the modified CMOS technology incorporating the AVT device may be characterized by presence of devices sharing features with more than one other type of device in the chip, in particular sharing an oxide layer with one type of device, and implants with another type of device. More particularly, the AVT device shares an oxide layer with a thin-oxide core transistor and implants with a thick-oxide I/O transistor. In a further embodiment a transistor may share an oxide layer with a thick-oxide I/O transistor and implants with a thin-oxide core transistor, as described in more detail below with reference to FIGS. 9-15. Such a transistor may be defined using the techniques described above with modifications to the definition of the masks and processes to apply the relevant oxide and implants.

Data is presented below demonstrating the expected performance of AVT devices. Unless otherwise stated FIGS. 2-7 below relate to a foundry 40 nm low-power CMOS technology using 1.1V thin-oxide devices and 2.5 thick-oxide devices

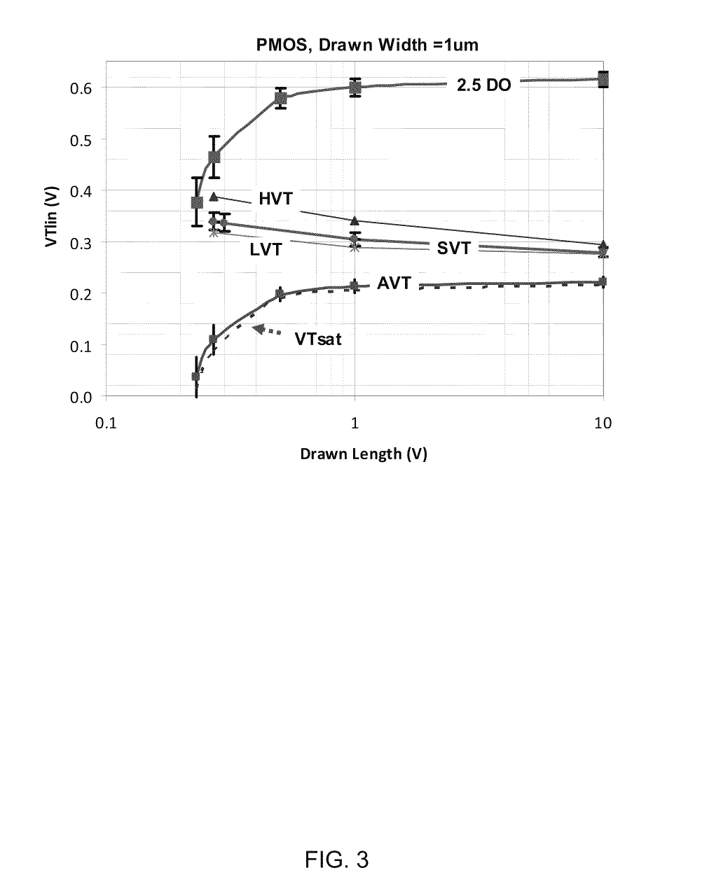

FIG. 3 shows a graph comparing the VTlin of thin-oxide core devices (LVT—Low Threshold Voltage, SVT—Standard Threshold Voltage, HVT—High Threshold Voltage), thick-oxide I/O devices and an AVT MOSFET according to the current disclosure, for varying drawn lengths.

At channel lengths significantly larger than the minimum length, the LVT, SVT and HVT devices all have very similar threshold voltages due to the use of pocket implants to generate the variants as opposed to channel implants. The pocket implants also lead to the reverse-short channel effect seen in the graph.

The AVT device provides a lower threshold voltage and retains the VT roll-off of the I/O device. The better gate control provided by the use of a thin-oxide gives a smaller difference in VT between L=10 μm and 0.23 μm compared to the I/O device.

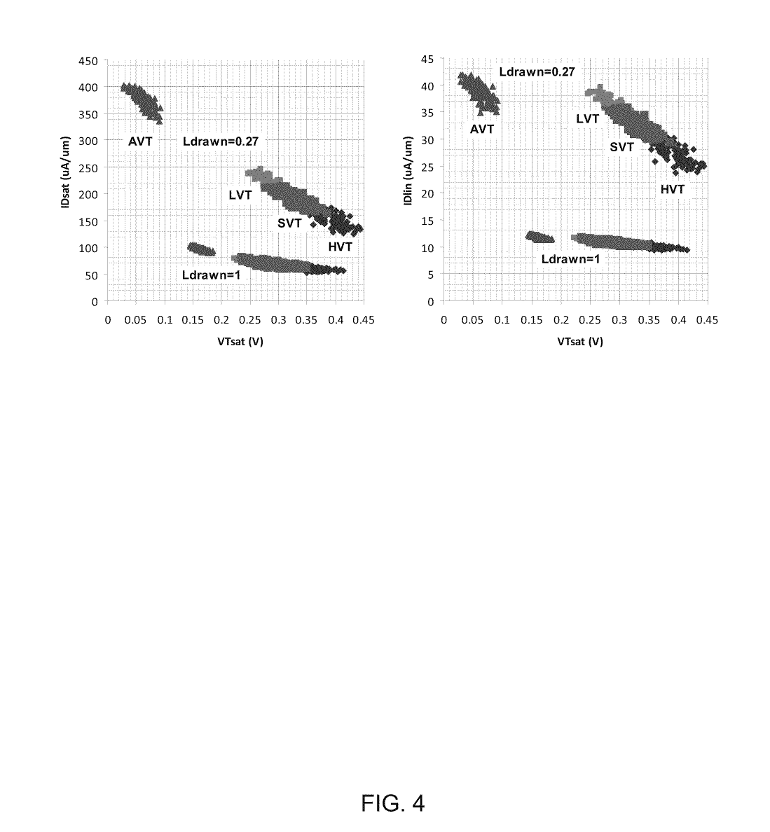

FIG. 4 shows plots of IDₛₐₜ and IDₗᵢₙ for the core, I/O and AVT devices as described previously in relation to FIG. 2. The IDₛₐₜ values for the AVT follow the general trend of the core devices while showing lower IDₗᵢₙ compared to an extrapolation of the core devices. This is caused by the higher resistance of the LDD implants from the I/O device used in the AVT.

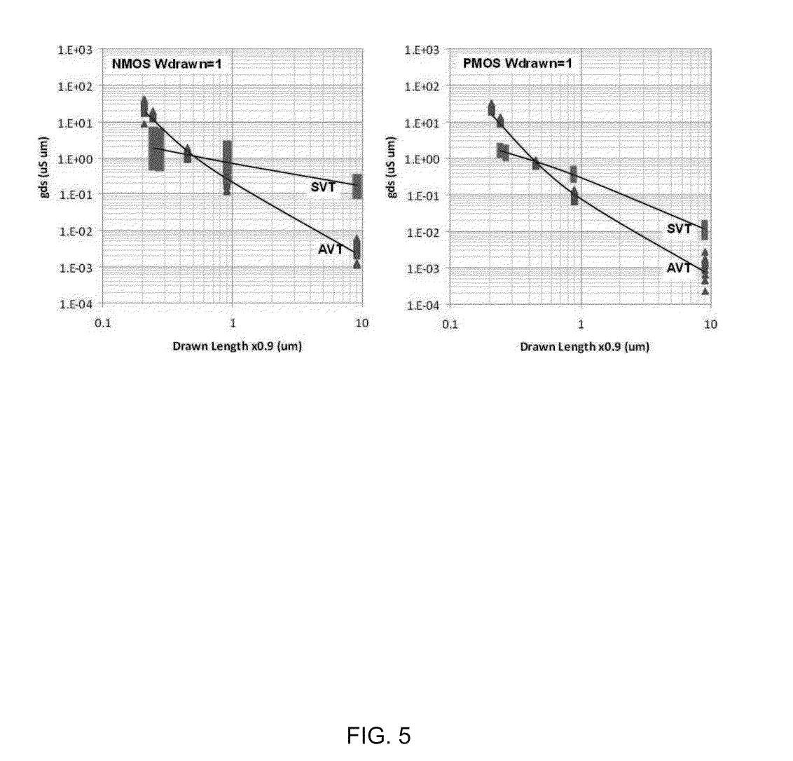

FIG. 5 shows plots of gds against drawn length for the SVT and AVT devices described previously. The SVT device has lower gds at short lengths due to better control of length modulation, but the AVT has lower gds for longer devices due to reduced DIBL.

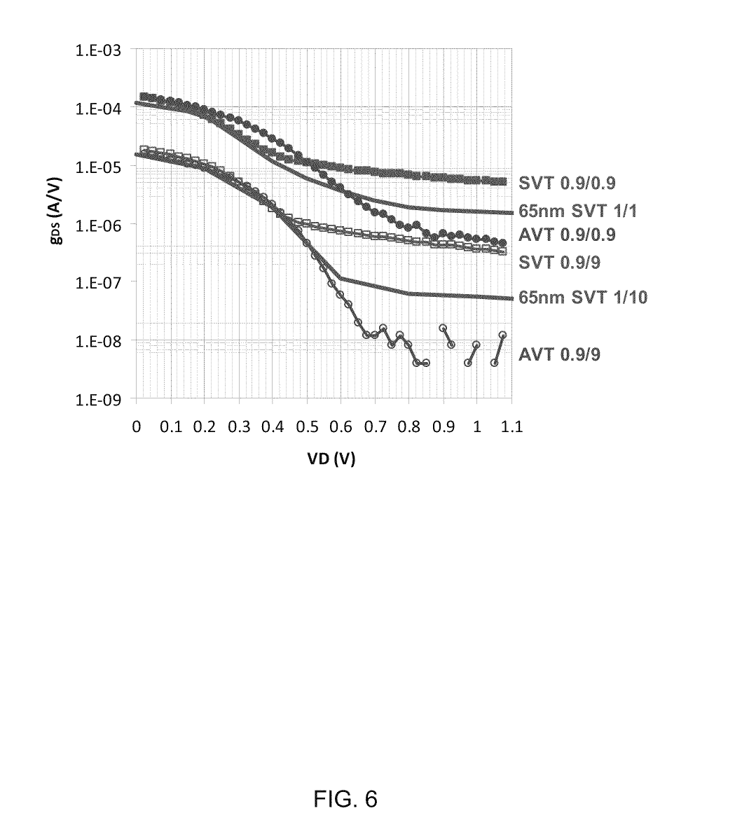

FIG. 6 shows a graph of gds against VD for AVT and SVT devices. The data for the 65 nm process node shows the degradation of a conventional thin-oxide core device at 40 nm compared to the 65 nm device, highlighting the need for the AVT device provided by the modified CMOS technology.

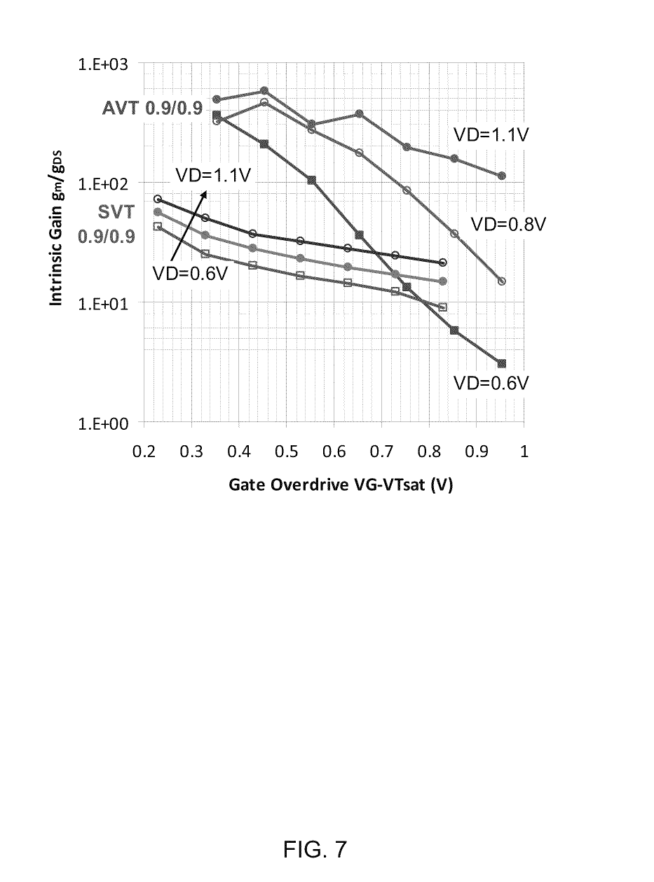

FIG. 7 shows intrinsic gain against gate overdrive voltage for SVT and AVT devices. The improvement of the intrinsic gain follows from the improved output conductance discussed above, while the differences in transconductance (gm) are minor. The improvement over SVT devices is most pronounced at small gate overdrive voltages, which is beneficial in analogue circuits.

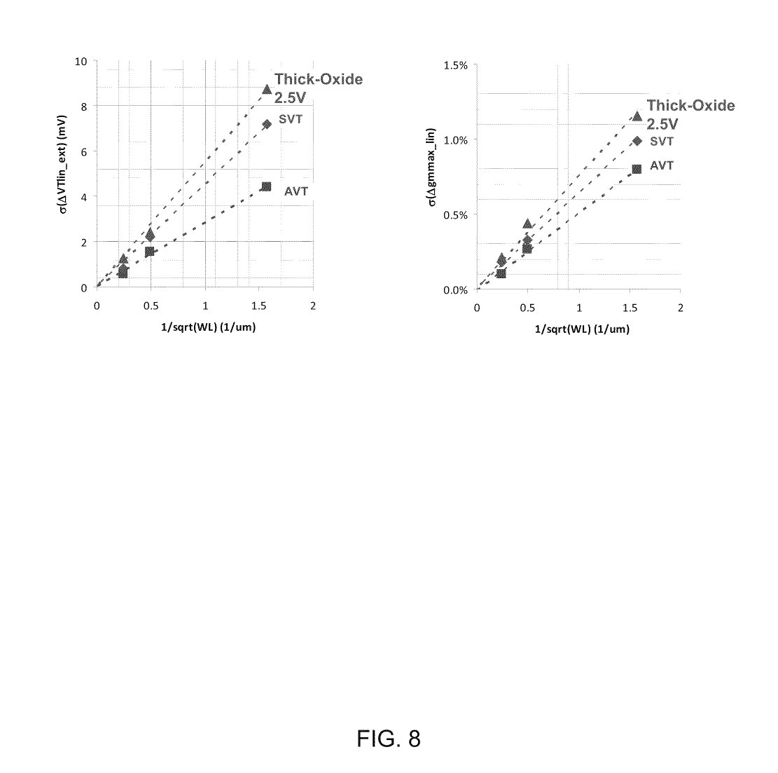

FIG. 8 shows a Pelgrom plot for the AVT device, showing improved device mismatch for the AVT compared to both SVT thin-oxide core devices and thick-oxide I/O devices.

As described above, in a further embodiment, a transistor may share an oxide layer with a thick oxide I/O transistor and implants with a thin-oxide core transistor in a dual oxide CMOS technology. FIG. 9 shows a cross section of conventional thin-oxide (core) device 10 and thick-oxide (I/O) MOS device 11, together with a new one-time programmable (OTP) non-volatile memory (NVM) device 900. The OTP transistor 900 comprises a thick oxide (or double gate oxide) 902 in a similar manner to the I/O-MOS device 11 and also comprises source/drain extensions 904 in a similar manner to the core MOS device 10. It can be seen that the core MOS device 10 has a thin oxide layer 906, unlike the OTP MOS device 900 and that the I/O-MOS device 11 does not comprise the same source/drain extensions as the OTP MOS device 900.

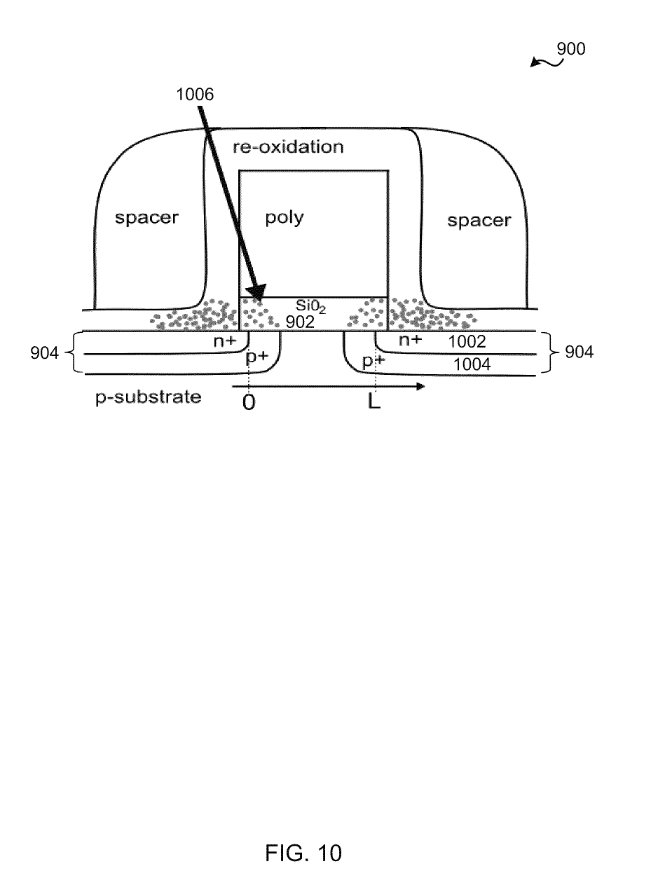

The thick oxide layer 902 in the OTP MOS device 900 may, for example, be 30-70 Å thick and in a particular example, the thick oxide layer 902 may be 52 Å thick. The source/drain extensions 904 are highly-doped, shallow and with pockets (as shown in FIG. 10 which is described below) and in this example, the source/drain extensions use the SVT (standard threshold voltage) implants. In other examples, other options for thin-gate implants may be used (e.g. LVT or HVT). In an embodiment, the available implant option (on the CMOS process being used) which provides the highest threshold voltage may be used (e.g. HVT, where the available options are LVT, SVT and HVT). FIG. 11 is an example graph which shows the effect of using different strength implants on threshold voltage.

FIG. 10 shows a more detailed cross section through the new OTP NVM device 900. It can be seen that the source/drain extensions 904 comprise high dose, shallow core LDD (lightly doped drain) implants 1002 which are the same polarity as the source/drain (n-doped in the example shown) and pocket (or halo) implants 1004 which are of the opposite polarity.

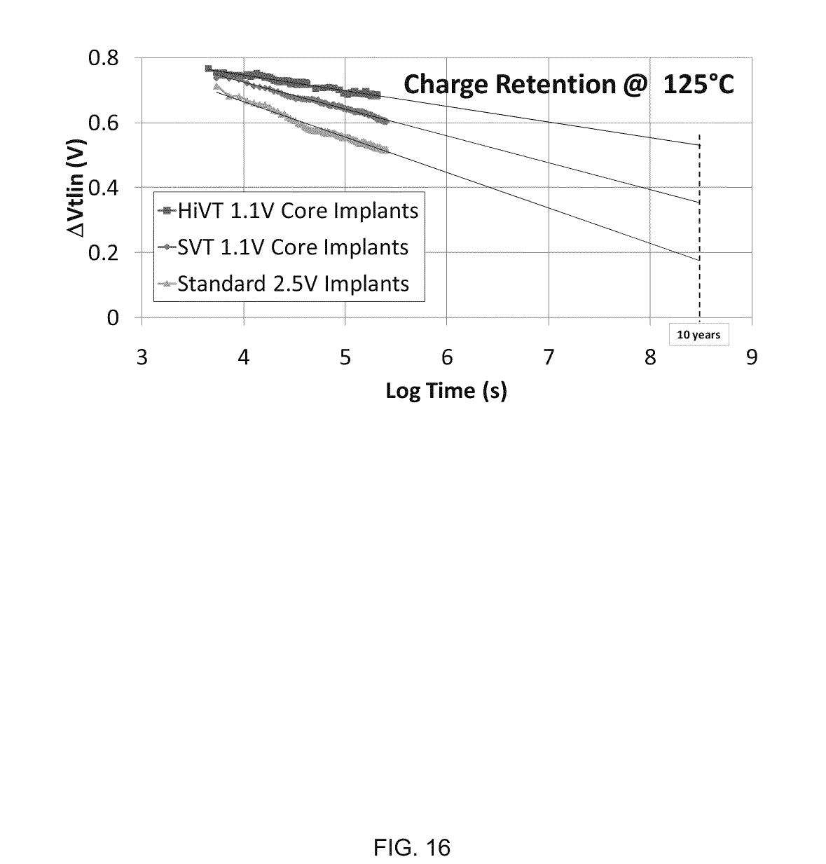

The use of thick gate oxide increases charge retention performance, due to lower tunneling probability compared with thinner oxide. However, when shallow and high dose source/drain extensions are implanted into the thick gate oxide, a high percentage of the implant species passes through the oxide and a part of it becomes lodged within the oxide. This creates additional charge traps along the edges of the gate and therefore introduces a process-induced trap area 1006 at the longitudinal gate edges. This process-induced trap area 1006 is focused on the key zones where the voltage threshold shift occurs because it is above the most doped channel areas. As a result, memory read margin of the OTP NVM device 900 is further enhanced because the process-induced trap area 1006 increases voltage threshold shift (as shown in FIG. 16 which is described below).

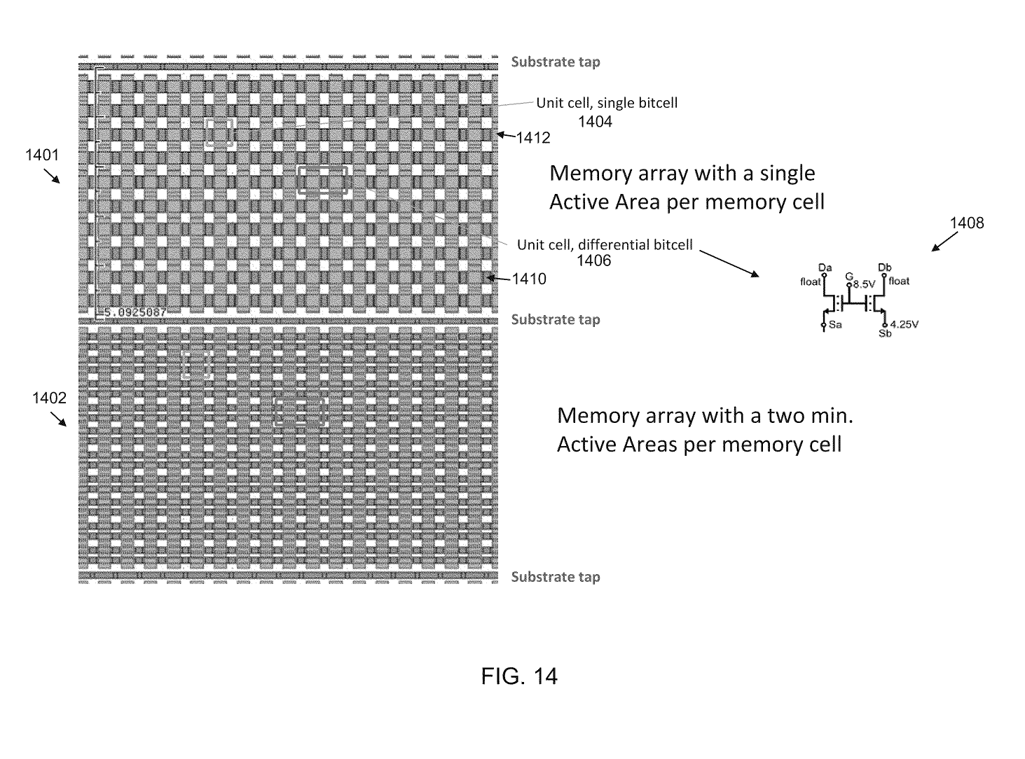

FIG. 10 shows the channel length, L, and because the additional trap sites are at the edges of the gate, if the channel length is reduced, the additional trap sites become more dominant, as is shown in the graph of FIG. 11. The strong LDD/pocket implants enables use of a much shorter minimum channel length, whilst still providing enhanced voltage threshold shift. In an embodiment, a channel length may be used which is much shorter than is typically used for an I/O transistor (such as device 11 in FIG. 9) and in some embodiments, the channel length may be selected to be as short as possible whilst still providing sufficient threshold voltage. By reducing the channel length, L, the bit-cell size of the device is reduced and a dense array of OTP memory cells (e.g. as shown in FIG. 14) can be built.

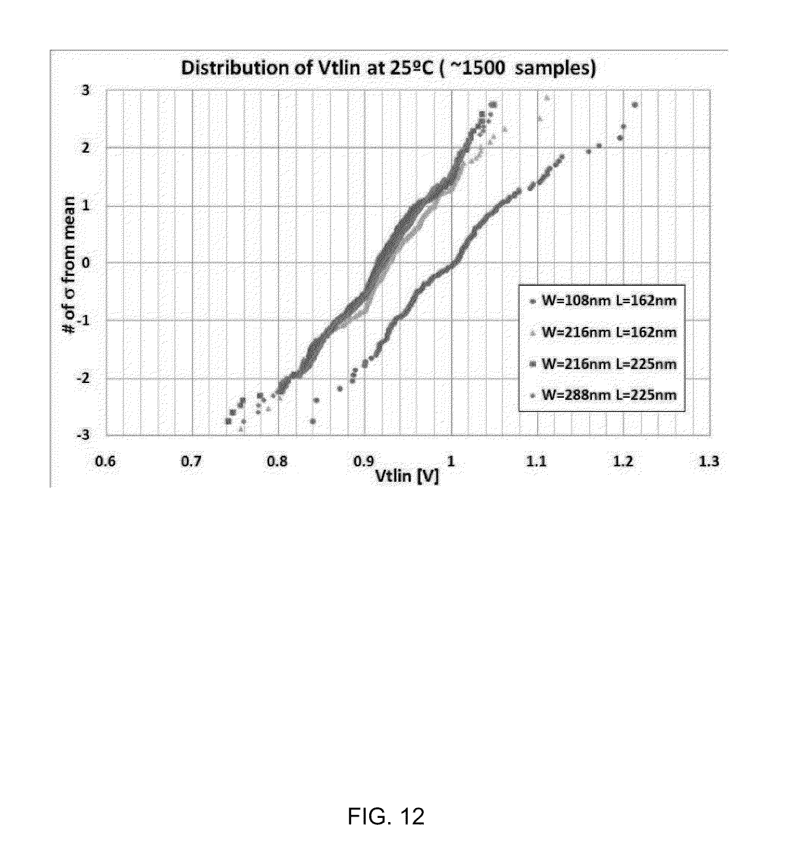

FIG. 12 shows some early experimental results where the width and length of the devices were varied. The parameter Vtlin is defined as:

V_{gs}@I_{ds}=10⁻⁷.W/L[A] with V_{ds}=50mV

It can be seen from these results that the shortest and narrowest device (W=108 nm and L=162 nm) has the highest threshold value.

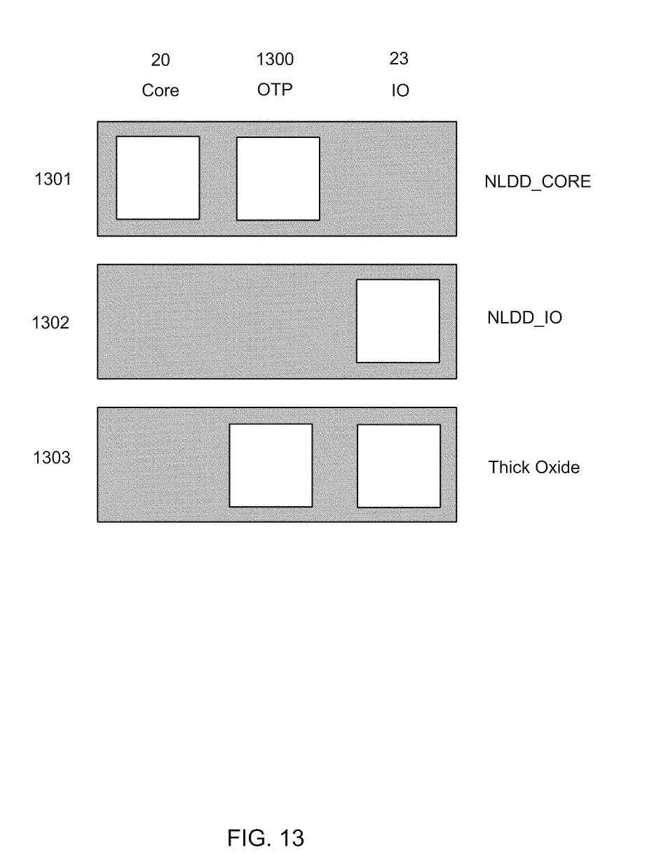

FIG. 13 shows a schematic diagram of a mask set for defining thin-oxide core, OTP and thick-oxide I/O transistors using standard CMOS technology without additional process steps. This diagram is analogous to that shown in FIG. 2 for the AVT devices. Openings in the mask show devices for which that process step is applied to for a particular device. As explained above, the word opening is not used to indicate a physical opening, but rather that that process step is applied to the indicated device. The active area, well & channel implants, gate-electrode and N⁺ or P+ masks are not shown as those steps are independent of the subject of this disclosure.

For the core device 20 the NLDD_CORE implant mask 1301 (LDD/pocket for thin gate oxide devices) is open but the NLDD_IO implant mask 1302 (LDD/pocket mask for thick gate oxide devices) is closed. In contrast the NLDD_IO implant mask 1302 is open for the I/O device 23, but the NLDD implant mask 1301 is closed. The thick oxide mask 1303 is open for the thick oxide I/O device 23 and not for the core device 20. The OTP device 1300 utilizes a new combination, with the thick oxide mask 1303 and NLDD_CORE implant mask 1301 open and the NLDD_IO implant mask 1302 closed. For the avoidance of doubt, for devices where the thick oxide mask is closed, a thin oxide is assumed to be present.

In a variation of the examples described above and where the CMOS process provides both SVT and HVT implants, an integrated circuit may be formed which comprises thin oxide transistors formed using SVT implants, thin oxide transistors formed using HVT implants and OTP transistors with thick oxide and using HVT implants. In a further variation, an OTP transistor may be formed with a thick oxide and an SRAM implant instead of using HVT implants. In such an instance, the SRAM mask may be modified instead of the HVT mask for formation of a particular OTP transistor. Consequently, where SRAM, SVT and HVT implants are all available, an integrated circuit may be formed which comprises thin oxide transistors formed using SVT implants, thin oxide transistors formed using HVT implants and OTP transistors with thick oxide and using SRAM implants.

In some examples, the highly-doped, shallow source/drain extensions with pockets may be formed in multiple steps to achieve transistors with different threshold voltages. In such an example, the implants resulting in the highest threshold voltage may be combined to form the OTP device.

The OTP device described herein is thus obtained by new features of the PDK utilized in the design of integrated circuits and in the mask layout process, e.g. the data preparation (Boolean algorithms) applied to the design data before mask manufacture commences. The modified CMOS technology provides new combinations of mask openings to provide the OTP device without adding process steps. An OTP device is thus characterized by utilizing a combination of features from the core and I/O devices provided by the conventional CMOS technology.

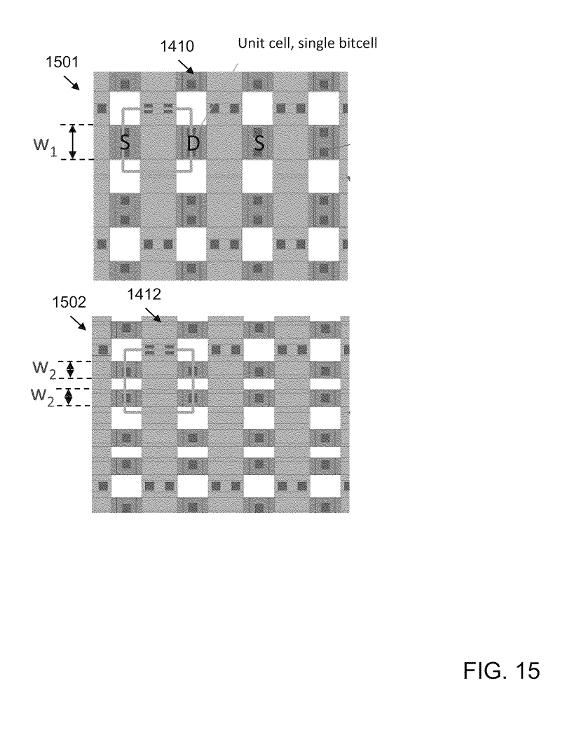

FIG. 14 shows two variants of an OTP array 1401, 1402. In each variant, two example unit cells are indicated: one unit cell 1404 is for a single bit cell comprising one transistor and the other unit cell 1406 is for a differential bit cell which comprises two transistors 1407, as shown in the example circuit diagram 1408. In the diagrams, two layers of the CMOS process are shown: the active area 1410 and the polysilicon 1412. The differences between the two variants of OTP unit cell can be seen more clearly in FIG. 15 which shows expanded views of portions 1501, 1502 of the views 1401, 1402 in FIG. 14. In the first variant, 1401, 1501, each OTP device has an active area of width w₁. However, as described above with reference to FIG. 12, there are benefits associated with narrower active areas. The programming effect of the OTP device increases as the width of the active area reduces; however because the area of the device reduces accordingly, the variability of the device increases. By using two narrow active areas (of width w₂), as shown in the second variant, 1402, 1502, the variability is improved whilst still achieving a bigger programming effect. In an example implementation, w₁=0.32 μm and w₂=0.12 μm with a 0.1 μm spacing between the two active areas. Further variations may use more than two active areas; however, the minimum width of an active area is likely to be set by processing technology and there is a trade-off between the increased performance offered by using multiple active areas and the resultant increase in bit-cell size. In the examples shown in FIGS. 14 and 15, by moving from the first variant to the second variant, a performance improvement is achieved without significantly increasing the bit-cell size.

The new OTP NVM device described above exploits the combination of thick gate oxide and aggressive source/drain extensions for Fowler-Nordheim tunneling as a programming method. This results in low power requirements for programming so that bit-cell may be programmed during the operation of the chip (if required). In addition, the new charge trapping sites improve the data retention performance compared to other OTP transistors and can be used to provide reliable OTP devices. Data retention tests show that the threshold voltage shift remains greater than 500 mV after 10 years at 125° C. The device can be integrated on existing dual gate oxide CMOS technology without any additional masks or process steps. FIG. 16 shows experimental results from data retention tests with different types of implant. As shown by the results, the OTP transistor provides a higher threshold voltage shift and better data retention than a standard transistor and HVT implants provide improved performance (in terms of data retention and threshold voltage shift) over SVT implants.

The example designs and results shown in FIGS. 12, 14 and 15 relate to devices fabricated using a 40 nm CMOS process. However, the designs and methods are also applicable to other CMOS processes, including 28, 65 and 90 nm technologies. The designs may be applied to any advanced CMOS technology which provides dual gate oxides and a heavy core implant.

The applicant hereby discloses in isolation each individual feature described herein and any combination of two or more such features, to the extent that such features or combinations are capable of being carried out based on the present specification as a whole in the light of the common general knowledge of a person skilled in the art, irrespective of whether such features or combinations of features solve any problems disclosed herein, and without limitation to the scope of the claims. The applicant indicates that aspects of the present invention may consist of any such individual feature or combination of features. In view of the foregoing description it will be evident to a person skilled in the art that various modifications may be made within the scope of the invention.

Any range or device value given herein may be extended or altered without losing the effect sought, as will be apparent to the skilled person.

It will be understood that the benefits and advantages described above may relate to one embodiment or may relate to several embodiments. The embodiments are not limited to those that solve any or all of the stated problems or those that have any or all of the stated benefits and advantages.

Any reference to ‘an’ item refers to one or more of those items. The term ‘comprising’ is used herein to mean including the method blocks or elements identified, but that such blocks or elements do not comprise an exclusive list and a method or apparatus may contain additional blocks or elements.

The steps of the methods described herein may be carried out in any suitable order, or simultaneously where appropriate. Additionally, individual blocks may be deleted from any of the methods without departing from the spirit and scope of the subject matter described herein. Aspects of any of the examples described above may be combined with aspects of any of the other examples described to form further examples without losing the effect sought.

It will be understood that the above description of a preferred embodiment is given by way of example only and that various modifications may be made by those skilled in the art. Although various embodiments have been described above with a certain degree of particularity, or with reference to one or more individual embodiments, those skilled in the art could make numerous alterations to the disclosed embodiments without departing from the spirit or scope of this invention.

What is claimed is:

1. A dual gate oxide CMOS integrated circuit, comprising
at least one thin-oxide transistor comprising a thin gate oxide and a first implant type comprising highly-doped, shallow source/drain extensions with pockets,
at least one thick-oxide transistor comprising a thick gate oxide and a second implant type, and
at least one further transistor comprising a thick gate oxide and implants comprising highly-doped, shallow source/drain extensions with pockets, the at least one further transistor forming a one-time programmable non-volatile memory device.

2. A dual gate oxide CMOS integrated circuit according to claim 1, wherein the one-time programmable non-volatile memory device is arranged to be programmable using Fowler-Nordheim tunneling.

3. A dual gate oxide CMOS integrated circuit according to claim 1, wherein the integrated circuit is fabricated using a CMOS process providing a plurality of different implant doses and wherein the highly-doped, shallow source/drain extensions with pockets for the one-time programmable non-volatile memory device are formed using a heaviest implant dose selected from the plurality of different implant doses.

4. A dual gate oxide CMOS integrated circuit according to claim 1, wherein the integrated circuit is fabricated using a CMOS process providing multiple implant steps to form transistors with different threshold voltages and wherein the highly-doped, shallow source/drain extensions with pockets for the one-time programmable non-volatile memory device are formed using an implant step producing a highest threshold voltage of all the multiple implant steps.

5. A dual gate oxide CMOS integrated circuit according to claim 1, wherein the integrated circuit is fabricated using a CMOS process providing SVT implants and HVT implants, wherein the highly-doped, shallow source/drain extensions with pockets in the one-time programmable non-volatile memory device are formed using HVT implants and wherein the highly-doped, shallow source/drain extensions with pockets in the at least one thin-oxide transistor are formed using SVT implants.

6. A dual gate oxide CMOS integrated circuit according to claim 1, wherein each transistor forming a one-time programmable non-volatile memory device comprises two parallel channel areas.

7. A dual gate oxide CMOS integrated circuit according to claim 6, wherein each of the two parallel channel areas has a width close to a minimum feature size supported by a CMOS process used to fabricate the integrated circuit and wherein the two parallel channel areas are separated by a distance close to a minimum spacing supported by the CMOS process.

8. A dual gate oxide CMOS integrated circuit according to claim 1, further comprising at least one further transistor comprising a thin gate oxide and the second implant type.

9. A mask set for the manufacture of a dual gate oxide CMOS integrated circuit, comprising
a first mask for the definition of LDD implants in a thin gate oxide transistor,
a second mask for the definition of a thick gate oxide,
wherein the first mask is open for the definition of LDD implants at a first site and the second mask is open for the definition of a thick gate oxide at that first site, for the formation of a transistor in the integrated circuit at that first site, the transistor formed at that first site comprising a one-time programmable non-volatile memory device.

10. A mask set according to claim 9, further comprising
a third mask for the definition of LDD implants in a thick gate oxide transistor,
wherein the third mask is closed at the first site.

11. A mask set according to claim 10, wherein
the second mask is closed for the definition of a thin gate oxide at a second site and the first mask is open for the definition of LDD implants at that second site, for the formation of a conventional thin-oxide transistor at that site, and
the third mask is open for the definition of LDD implants at a third site and the second mask is open for the definition of a thick gate oxide at that third site, for the formation of a conventional thick-oxide transistor at that site.

12. A mask set according to claim 11, wherein
the third mask is open for the definition of LDD implants at a fourth site and the second mask is closed for the definition of a thin gate oxide at that fourth site, for the formation of a transistor in the integrated circuit at that fourth site.

13. A mask set according to claim 11, wherein the first mask is for the definition of HVT LDD implants in a thin gate oxide transistor.

14. A mask set according to claim 13, further comprising:
a fourth mask for the definition of SVT LDD implants in a thin gate oxide transistor, and
wherein the second mask is closed for the definition of a thin gate oxide at a fifth site and the fourth mask is open for the definition of SVT LDD implants at that fifth site, for the formation of a SVT thin-oxide transistor at that site.

15. A method for the manufacture of a dual-oxide CMOS integrated circuit, comprising the steps of
forming a thin-oxide transistor using a first implant type and a thin oxide configuration, the first implant type comprising highly-doped, shallow source/drain extensions with pockets,
forming a thick-oxide transistor using a second implant type and a thick oxide configuration, and
forming a third type of transistor using the thick oxide configuration and the first implant type, the third type of transistor forming a one-time programmable non-volatile memory device.

16. A method for the manufacture of a dual-oxide CMOS integrated circuit according to claim 15, the method of manufacture comprising a plurality of implant doses and the first implant type comprising a heaviest of the plurality of implant doses.

17. A method for the manufacture of a dual-oxide CMOS integrated circuit according to claim 16, the plurality of implant doses comprising SVT and HVT and wherein the highly-doped, shallow source/drain extensions with pockets are formed using HVT implants.

18. A method for the manufacture of a dual-oxide CMOS integrated circuit according to claim 17, further comprising:
forming a thin-oxide transistor using a thin oxide configuration and highly-doped, shallow source/drain extensions with pockets formed using SVT implants.

19. A method for the manufacture of a dual-oxide CMOS integrated circuit according to claim 15, further comprising the step of forming a fourth type of transistor using the thin oxide configuration and the second implant type.

20. A method for the manufacture of a dual-oxide CMOS integrated circuit according to claim 15, using a mask set comprising:
a first mask for the definition of LDD implants in a thin gate oxide transistor,
a second mask for the definition of a thick gate oxide, and
a third mask for the definition of LDD implants in a thick gate oxide transistor,
and wherein the first mask is open for the definition of LDD implants at a first site, the second mask is open for the definition of a thick gate oxide at that first site and the third mask is closed at the first site for the formation of the third type of transistor in the integrated circuit at that first site.
